(19) United States
(12) Patent Application Publication
(10) Pub. No.: US 2001/0054722 A1
(43) Pub. Date: Dec. 27, 2001

(54) Charge-coupled device as well as a solid-state image pick-up device comprising a charge-coupled device

(76) Inventor: Jan Theodoor Jozef Bosiers, Eindhoven (NL)

Correspondence Address: Corporate Patent Counsel, U.S. Philips Corporation, 580 White Plains Road, Tarrytown, NY, 10591, US

(21) Appl. No.: 09/790,597

(22) Filed: Feb. 22, 2001

(30) Foreign Application Priority Data
Feb. 24, 2000 (EP) 00200648.4

(51) Int. Cl. H01L 29/768; H01L 31/0376

(52) U.S. Cl. 257/215

(57) ABSTRACT

In general, the output of a buried channel CCD is provided with a floating diffusion (4), which forms a storage site to determine the size of an electric charge. For this purpose, the floating diffusion may be connected to the input of an amplifier, such as a source follower (8). The charge is transferred to the floating zone from below an output gate OG to which a DC voltage is applied. To obtain a high sensitivity, i.e. a high voltage per electron, it is important to keep the capacitance of the floating zone as small as possible. The capacitance can be reduced by narrowing the channel at the output. This method of reducing C, however, is limited in known structures because this shape of the channel may induce an electric field in the channel which counteracts the transfer to the floating zone. To suppress this effect, the gate oxide (5) below the output gate is provided with a thicker part (5b) adjoining the floating diffusion (4). By virtue thereof, an additional field is induced below the output gate, which enhances the transfer of charge to the floating zone. This enables the channel to be narrowed, resulting in a low floating-zone capacitance, without decreasing the transfer efficiency. Said capacitance is reduced further by the thick oxide, which leads to a small capacitance between the floating zone and the output gate.

The invention relates to a buried channel charge-coupled device comprising a semiconductor body which is provided, at a surface, with a buried channel in the form of a surface zone of a first conductivity type adjoining said surface, which surface zone of a first conductivity type is bounded in the semiconductor body by a surface region of the opposite, i.e. the second, conductivity type, the surface above the buried channel being provided with an electrically insulating layer which forms a gate dielectric on which a row of electrodes is provided to apply voltages for transporting electric charge packets through the buried channel to an output comprising an electrically floating zone of the first conductivity type, which is connected to an output amplifier, the last electrode of the row of electrodes, hereinafter referred to as output gate, situated in front of the floating zone, being provided with connection means for applying a DC voltage. The invention also relates to a solid-state image pick-up device comprising such a charge-coupled device.

A charge-coupled device of the type described hereinabove, which is disclosed, inter alia, in Japanese patent application 07/074345 A, laid open to public inspection, can be used, for example, as a horizontal read-out register in a two-dimensional charge-coupled image pick-up device. Via this read-out register, the charge packets are successively transported to the floating zone, on which they are converted to voltage variations which are read out via the output amplifier (generally a source-follower circuit). For a signal to be useful, also at a very low light intensity, the sensitivity of the output must be high, i.e. the conversion factor V/electron of the floating zone must be as large as possible. In this connection, it is desired for the capacitance of the floating zone to be as small as possible. In the charge-coupled device known from the above-mentioned Japanese application 07/074345, this object is achieved by narrowing the horizontal read-out register at the location of the output gate. However, the degree to which the channel can be narrowed is limited because the narrowed portion in the channel may induce an electric field that counteracts the charge transport. In addition, there is a tendency to reduce the clock voltages at which the device is operated, for example, to 3.3 V and lower, as a result of which a gate having a greater length dimension, or widening of the output gate and the underlying channel, become desirable.

Generally, an increase of the length of the gate is impossible because it entails a deceleration of the device. An increase of the width of the output gate is undesirable because, as explained hereinabove, this leads to an increase of the capacitance of the floating zone.

It is an object of the invention to provide, inter alia, a design which enables a further reduction of the capacitance of the floating zone, while avoiding the above-mentioned problems. To achieve this, a charge-coupled device of the type mentioned in the opening paragraph is characterized in accordance with the invention in that the part of the electrically insulating layer situated below the output gate has a non-uniform thickness and, viewed in the direction of the charge transport, comprises a first portion of comparatively small thickness and an adjoining second portion of comparatively large thickness, adjoining the electrically floating zone and being situated between this zone and said first portion. As a result of this profiling of the thickness of the gate dielectric below the output gate, a drift field is induced in the channel, which enhances the charge transport to the floating gate. By virtue thereof, the length of the output gate can be increased (within certain limits of course), while maintaining a sufficiently rapid charge transport from the output gate to the floating zone. While avoiding a field counteracting the charge transport, this additional field also enables a larger width reduction of the channel at the location of the output than in the absence of the profiled gate dielectric below the output gate, so that a further reduction of the capacitance of the floating zone can be achieved. This capacitance has additionally already been reduced by the thicker dielectric next to the floating zone as a result of a reduction of the capacitance between the zone and the output gate (which capacitance forms an important component of the overall capacitance of the floating zone).

The invention can be advantageously employed in devices comprising a buried channel of uniform width. A preferred embodiment wherein particular advantages are achieved is characterized in that, in a direction parallel to the surface and transverse to the charge-transport direction, the width of the buried channel is tapered in form at the location of the output gate and, viewed in the direction from the output gate to the electrically floating gate, the width becomes smaller.

The dielectric layer below the other electrodes may be uniform in thickness. An important embodiment having the advantage that the gate dielectric below the output gate and the gate dielectric below the other gates can be manufactured simultaneously is characterized in that the profile of the electrically insulating layer below the other electrodes corresponds to the profile of the electrically insulating layer below the output gate, so that, below these electrodes, an asymmetric potential distribution in the channel is obtained when said voltages are applied. The charge-coupled device can be advantageously operated as a 2-phase CCD.

These and other aspects of the invention will be apparent from and elucidated with reference to the embodiment(s) described hereinafter.

In the drawings:

FIG. 1 is a plan view of a charge-coupled device in accordance with the state of the art;

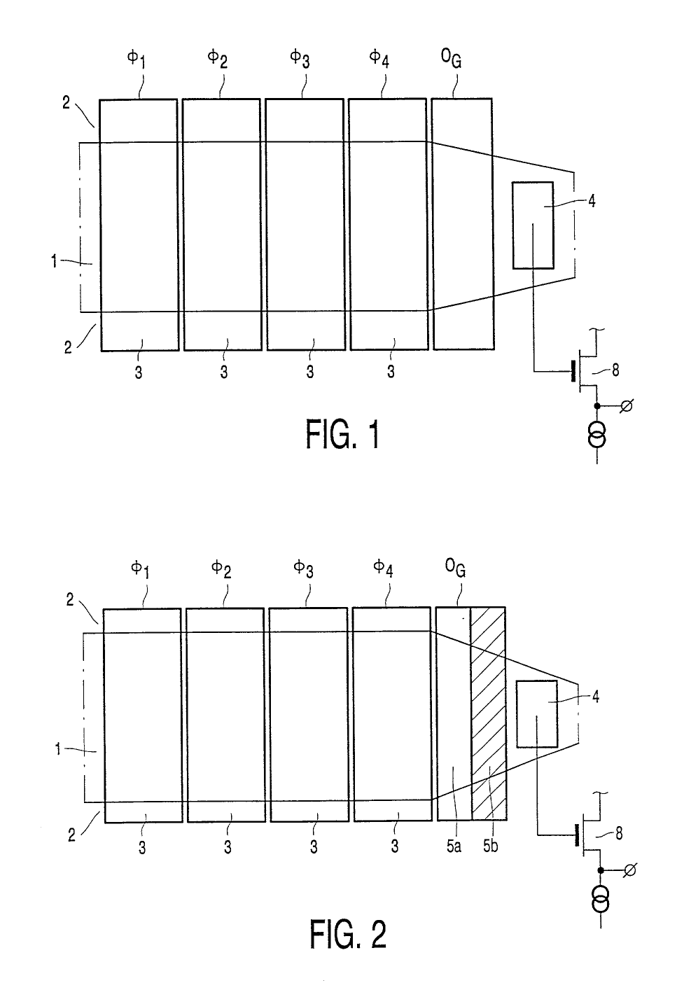

FIG. 2 is a plan view of a charge-coupled device in accordance with the invention;

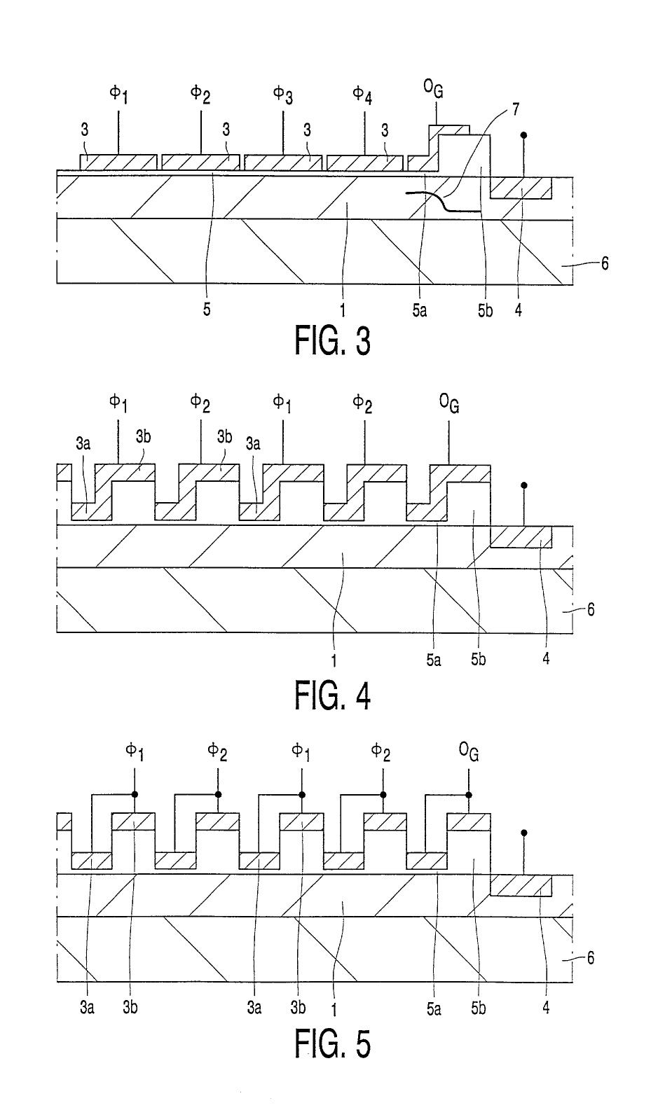

FIG. 3 is a cross-sectional view of this device taken on the line II-II;

FIG. 4 is a cross-sectional view of a second embodiment of a charge-coupled device in accordance with the invention;

FIG. 5 is a cross-sectional view of a further modification of a charge-coupled device in accordance with the invention.

The invention is illustrated by means of a diagrammatic plan view shown in FIG. 1, wherein the output portion of a buried channel charge-coupled device, which is known per se, is shown, which charge-coupled device is assumed to be of the n-type, for the sake of simplicity. The channel is formed by an n-type region or zone 1, which is situated at the surface of the semiconductor body and is laterally bounded, within the semiconductor body, by a p-type region 2. The surface is provided with a row of electrodes 3 for controlling storage and transport of the electric charge in the channel. For this purpose, clock voltages φ are applied to the electrodes 3, for example four clock voltages altogether in the case of a four-phase CCD. The electrodes 3 are followed by an output gate OG to which a DC voltage is applied during operation. An electrically floating zone 4 in the form of a highly doped n-type zone is provided next to the electrode OG and connected to the input of a source follower 8. A reset transistor, which is not shown in the drawing because it does not form part of the invention, is generally arranged behind the floating zone 4. To obtain a high sensitivity, it is important that the capacitance coupled to the floating zone is as small as possible. In this connection, the channel 1 is tapered at the location of the output, resulting in a reduction of, in particular, the capacitance between the zone 4 and the output gate OG. The degree to which the channel is narrowed cannot be arbitrarily selected since the shape of the channel below the gate OG causes an electric field to be induced which counteracts the charge transport of electrons below the output gate to the floating zone 4. This field may cause the charge transport to be delayed, as a result of which the device can be used at lower frequencies or, if the device is operated at a higher frequency, degradation of the output signals takes place, which can be attributed to the fact that in the charge transport a part of the electric charge is left behind. As a result, it is generally impossible to narrow the channel so much at the location of the output gate as would be desirable with a view to the capacitance of the floating zone.

FIG. 2 and FIG. 3 show, respectively, a plan view and a cross-sectional view of a first embodiment of a charge-coupled device in accordance with the invention, wherein this drawback is at least substantially obviated. For the sake of convenience, corresponding parts in these Figures bear the same reference numerals as in FIG. 1. As is shown in FIG. 2, the degree to which the channel 1 is narrowed at the location of the output gate OG is much larger than in the embodiment shown in FIG. 1, so that the capacitance between the output gate and the floating gate 4 is much smaller. To make sure that this does not give rise to a counteracting electric field below the output gate, the gate dielectric 5 (see FIG. 3) below the output gate OG is provided in the form of an electrically insulating layer, in this example a layer of silicon oxide of non-uniform thickness comprising a first portion (viewed in the transport direction from left to right) 5a of comparatively small thickness and a contiguous second portion 5b of comparatively large thickness, which is situated next to the floating gate 4. In the plan view shown in FIG. 2, the part of the output gate OG situated on the thicker oxide is hatched.

As shown in FIG. 3, the n-type charge-transport channel 1 is bounded, on the side opposite the electrodes 3, by a p-type region 6, which may extend across the whole thickness of the semiconductor body or, in the case of an image pick-up device with vertical anti-blooming, across a part of the thickness of the semiconductor body, after which it blends with an n-type substrate (not shown in the drawing), which constitutes a drain for electric charge generated by overexposure. Apart from the thick oxide 5b, the thickness of the oxide layer above the charge transport channel is substantially uniform, said thickness being equal or substantially equal to the thickness of the thinner oxide 5a below the output gate. A specific value of the thickness of the oxide layer 5 (5a) is, for example, 8 nm. The thickness of the oxide layer 5b is, for example, 140 nm. The device as shown in FIG. 3 is operated as a 4-phase CCD, which is diagrammatically indicated by the clock voltages φ₁, φ₂, φ₃, φ₄. The device can of course also be operated as a 3-phase or 5-phase device. A modification, which can be operated as a 2-phase CCD, is shown in cross-section in FIG. 4. This device substantially only differs from that shown in FIG. 3 in that the gate dielectric 5 below the electrodes 3 is also provided with a step in the oxide thickness, which is comparable to the step 5a, 5b below the output gate OG. As is commonly known, upon applying a voltage to the gates 3, the oxide step enables an asymmetry in the potential distribution in the transport duct below the gates, as a result of which a charge transport direction enabling 2-phase operation is induced.

A further modification is shown in the cross-sectional view of FIG. 5. This embodiment differs from that shown in FIG. 4 in that each electrode 3 and the output gate OG are composed of two portions a, b, which are made from two different, deposited layers, such as two layers of polycrystalline silicon, which are conductively connected to each other by, for example, metal connections (diagrammatically shown). To illustrate the effect of the oxide step below the output gate OG, the line 7 in FIG. 3 denotes the potential distribution at a specific voltage on OG. As a result of the step in the oxide 5, the potential distribution 7 also demonstrates a step with which an electric field corresponds, which exerts a driving force on the electrons in the channel in the direction of the floating zone 4. A counteracting field caused by the constriction of the channel at the location of the output can be compensated completely, or at least to a substantial degree, by this field. If the step in the oxide 5 below the output gate is chosen to be sufficiently large, the channel can be embodied so as to be very narrow at the location of the output, thus enabling a further reduction of the capacitance of the floating zone, while maintaining a good transfer efficiency below the output gate.

It will be clear that the invention is not limited to the examples described herein, and that, within the scope of the invention, many variations are possible to those skilled in the art. For example, instead of the tapered constriction (which has certain advantages in terms of a favorable field distribution), differently shaped constrictions can alternatively be used. Apart from n-channel devices, the invention can also be advantageously applied to p-channel devices.

1. A buried channel charge-coupled device comprising a semiconductor body which is provided, at a surface, with a buried channel in the form of a surface zone of a first conductivity type adjoining said surface, which surface zone of a first conductivity type is bounded in the semiconductor body by a surface region of the opposite, i.e. the second, conductivity type, the surface above the buried channel being provided with an electrically insulating layer which forms a gate dielectric on which a row of electrodes is provided to apply voltages for transporting electric charge packets through the buried channel to an output comprising an electrically floating zone of the first conductivity type, which is connected to an output amplifier, the last electrode of the row of electrodes, hereinafter referred to as output gate, situated in front of the floating zone, being provided with connection means for applying a DC voltage, characterized in that the part of the electrically insulating layer situated below the output gate has a non-uniform thickness and, viewed in the direction of the charge transport, comprises a first portion of comparatively small thickness and an adjoining second portion of comparatively large thickness adjoining the electrically floating zone and being situated between this zone and said first portion.

2. A charge-coupled device as claimed in claim 1, characterized in that, in a direction parallel to the surface and transverse to the charge-transport direction, the width of the buried channel is tapered in form at the location of the output gate and, viewed in the direction from the output gate to the electrically floating gate, the width becomes smaller.

3. A charge-coupled device as claimed in claim 1 or 2, characterized in that the the profile of the electrically insulating layer below the other electrodes corresponds to the profile of the electrically insulating layer below the output gate, so that, below these electrodes, an asymmetric potential distribution in the channel is obtained when said voltages are applied.

4. A charge-coupled device as claimed in claim 3, characterized in that the device forms a 2-phase charge-coupled device.

5. A solid-state image pick-up device comprising a charge-coupled device as claimed in any one of the preceding claims.
